(19) United States
(12) Patent Application Publication
(10) Pub. No.: US 2006/0046497 A1
(43) Pub. Date: Mar. 2, 2006

(54) Manufacturing method

(75) Inventor: Nobukazu Teranishi, Shinagawa-ku (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/210,117

(22) Filed: Aug. 24, 2005

(30) Foreign Application Priority Data
Aug. 24, 2004 (JP) 2004-244420

(51) Int. Cl. H01L 21/302; G03C 5/00; H01L 21/311

(52) U.S. Cl. 438/735; 438/736; 438/697; 438/701; 430/313; 438/725; 438/699

(57) ABSTRACT

A manufacturing method according to which surface unevenness of a workpiece on which microprocessing is performed such as a semiconductor substrate or a micromachine is readily flattened with a higher degree of flatness than the prior art even when depressions vary in depth, to thus facilitate the processing of the surface in a subsequent process. The manufacturing method includes the processes of applying a photosensitive resin 2 over the surface of a workpiece 1, exposing the applied resin using a grayscale mask 3 that corresponds to the surface shape of the resin, and developing the exposed resin and eliminating unhardened resin.

### BACKGROUND OF THE INVENTION

1. Field of the Invention

The present invention relates to a manufacturing method for micromachines, semiconductor devices and the like, and in particular to technology for flattening surface unevenness of a workpiece to facilitate processing of the surface in a subsequent process.

2. Related Art

In recent years, precision processed products on which microprocessing is performed such as micromachines and semiconductor devices are becoming more and more detailed, creating demands for further improvements in processing precision.

Here, “micromachine” is a general term used to describe mechanical systems such as minute machines and robots of a few millimeters or less in size. Micromachines include cogwheels and motors of a few microns in diameter created by utilizing semiconductor microprocessing technology, and miniature autonomous mobile robots created using mechatronic technology.

With semiconductor devices, electronic performance is created by physically combining p-type and n-type semiconductors formed respectively by adding impurities such as boron and phosphorous to an intrinsic semiconductor such as pure silicon or the like.

In manufacturing semiconductor substrates, for example, depressions and protrusions in the substrate surface result from wiring, gates and the like. Since this unevenness, left as is, hinders microprocessing by making it difficult to adjust the depth of focus etc., the unevenness preferably is flattened before the next process.

Here, Japanese Patent Application Publication No. 2-181967 discloses a color solid-state imaging apparatus that suppresses uneven resist application to eliminate color unevenness by forming on-chip color filters directly on a solid-state imaging device after firstly using a high molecular material to fill in any depressions in the surface of the semiconductor substrate on which the solid-state imaging device is formed and flatten the substrate surface.

Japanese Patent Application Publication No. 4-233273 discloses a color solid-state imaging apparatus and a manufacturing method for the same in which the thickness of a flattening layer is suppressed to eliminate mixed colors. To achieve this a flattening layer is formed by applying a transparent high polymer resin over the surface of a semiconductor substrate in which a solid-state imaging device is formed so that the resin remains only in depressions in the substrate surface, and then forming color filters on the flattening layer.

In terms of conventional technology concerning the present invention, Japanese Patent Application Publications No. 2003-91066 and No. 8-174563 disclose in detail about grayscale masks.

However, while Japanese Patent Application Publication No. 2-181967 recites that a flattened substrate is obtained by spin coating a photosensitive resin over the substrate surface and selectively hardening portions of the applied resin corresponding to depressions in the substrate surface, the surface of these portions corresponding to depressions in the supposedly flattened substrate actually harden in the shape in which the photosensitive resin is spin coated. This results in the middle of depressions exceeding 1 μm in depth being caved in while the periphery of the depressions stick up above surrounding areas of the substrate, creating a height difference with the surrounding areas. Such a substrate can hardly be described as having a high degree of flatness.

Also, while Japanese Patent Application Publication No. 4-233273 discloses a method for filling in depressions over two stages in the case of depressions having two depth levels, this method both increases the number of processes because of having to repeat the processing for the number of depth levels and cannot be applied in the case of depressions in which the difference in depth is continuous.

### SUMMARY OF THE INVENTION

In view of the above problems, the present invention aims to provide a manufacturing method according to which surface unevenness of a workpiece on which microprocessing is performed such as a semiconductor substrate or a micromachine is readily flattened with a higher degree of flatness than the prior art even when depressions vary in depth, to thus facilitate processing of the surface in a subsequent step.

To achieve the above object, a manufacturing method pertaining to the present invention is for flattening surface unevenness of a workpiece to facilitate processing of the workpiece surface in a subsequent step, and includes an application step of applying a photosensitive resin over the workpiece surface, an exposure step of exposing the applied photosensitive resin using a grayscale mask that corresponds to a surface shape of the photosensitive resin, and a developing step of developing the exposed photosensitive resin and eliminating unhardened photosensitive resin.

According to this structure, the photosensitive resin is exposed using a grayscale mask that corresponds to the surface shape of the applied photosensitive resin, thus enabling any adverse effect that unevenness of the resin surface caused by unevenness of the workpiece surface may have to be substantially eliminated.

Even when depressions in the workpiece surface vary in depth, flattening can thus be readily performed in a single operation with a higher degree of flatness than the prior art, to facilitate processing of the surface in a subsequent step.

Here, the photosensitive resin may be exposed in the exposure step to enable the workpiece surface to be flattened, and the manufacturing method may further include, after the developing step, a heating step of increasing a degree of flatness by applying heat and softening hardened photosensitive resin.

According to this structure, heat is applied to hardened photosensitive resin after the developing to soften the resin and stabilize the shape thereof, thus allowing for depressions inadequately filled with resin due to mask misalignment or underexposure etc. to be filled in and flattened.

Here, the photosensitive resin may be exposed in the exposure step to enable the workpiece surface to be flattened, and the manufacturing method may further include, after the developing step, a secondary application step of increasing a degree of flatness by applying a flattening material uniformly on the workpiece surface.

According to this structure, a flattening material is applied uniformly after the developing, thus allowing for depressions inadequately filled with photosensitive resin due to mask misalignment or underexposure etc. to be filled in and flattened.

Here, the manufacturing method may further include, before the application step, a film formation step of forming a film of substantially uniform thickness on the workpiece surface using a predetermined material, the photosensitive resin may be applied on the film in the application step, and the manufacturing method may further include, after the developing step, an etching step of flattening the workpiece surface by uniformly etching the workpiece surface on which hardened photosensitive resin remains in depressions in the film.

This structure enables the surface of the workpiece to be flattened by applying a predetermined material other than photosensitive resin.

Here, the manufacturing method may further include, before the film formation step, a cavity formation step of forming a cavity by hollowing out part of the workpiece surface where the predetermined material is to be formed, and the etching may be performed in the etching step until the predetermined material is formed only in the cavity.

This structure enables the surface of the workpiece to be flattened while leaving the predetermined material formed at a substantially uniform thickness only in concave portions of the surface, and thus to create wiring patterns and insulating films etc. without reducing the degree of flatness.

Here, the predetermined material and the hardened photosensitive resin may have substantially the same etching rate, and the photosensitive resin may be exposed in the exposure step to enable the workpiece surface to be flattened.

When the etching rates of the predetermined material and the photosensitive resin are substantially the same, this structure enables the surface of the workpiece to be flattened by performing etching uniformly after exposing the photosensitive resin to enable the surface of the workpiece on which the film of predetermined material was formed to be flattened.

Here, the predetermined material and the hardened photosensitive resin may have different etching rates, and in the exposure step, a hardening rate of the photosensitive resin may be changed according to a shape of the surface unevenness and a difference or a ratio of the etching rates.

When the etching rates of the predetermined material and the photosensitive resin differ, this structure enables the surface of the workpiece after etching to be flattened because of the hardening rate of the photosensitive resin being changed according the shape of the surface unevenness and the difference or ratio of the etching rates.

Here, the predetermined material and the hardened photosensitive resin may have different etching rates, and the grayscale mask may be created so that a hardening rate of the photosensitive resin changes according to a shape of the surface unevenness and a difference or a ratio of the etching rates.

When the etching rates of the predetermined material and the photosensitive resin differ, this structure enables the surface of the workpiece after etching to be flattened because of the grayscale mask being patterned so that the hardening rate of the photosensitive resin changes according to the shape of the surface unevenness and the difference or ratio of the etching rates.

Here, the workpiece may be a semiconductor substrate, and the predetermined material may be any of copper, aluminum, silicon dioxide, and silicon nitride.

This structure enables wiring patterns using copper or aluminum and insulating films using silicon dioxide or silicon nitride to be created on the surface of a semiconductor substrate without reducing the degree of flatness.

Here, the workpiece may be one of a semiconductor substrate and a micromachine.

This structure enables the surface of semiconductor substrates and micromachines to be flattened.

### BRIEF DESCRIPTION OF THE DRAWINGS

These and other objects, advantages, and features of the invention will become apparent from the following description thereof taken in conjunction with the accompanying drawings, which illustrate specific embodiments of the present invention.

In the drawings:

FIG. 1 shows an outline of a manufacturing line 10 in an embodiment 1 of the present invention;

FIG. 2A schematically shows a cross-section of a semiconductor substrate 1 (i.e. workpiece) having a solid-state imaging device formed therein;

FIG. 2B shows FIG. 2A from above, FIG. 2A being the cross-section cut at A-A′;

FIG. 3A schematically shows a cross-section of a transparent photosensitive resin 2 spin coated on semiconductor substrate 1 of FIGS. 2A and 2B;

FIG. 3B shows FIG. 3A from above, FIG. 3A being the cross-section cut at A-A′;

FIG. 4A schematically shows a grayscale mask 3 for use with semiconductor substrate 1 patterned by applying chromium 3B to a transparent film 3A while varying the transparency per section;

FIG. 4B shows a cross-section of FIG. 4A cut at A-A′;

FIG. 4C schematically shows a grayscale mask 4 for use with semiconductor substrate 1 patterned by applying chromium 4B to a transparent film 4A while varying the number of fine dots at or below the resolution per section;

FIG. 4D shows a cross-section of FIG. 4C cut at B-B′;

FIG. 5 schematically shows a cross-section of grayscale mask 3 of FIGS. 4A and 4B being used to expose semiconductor substrate 1 having photosensitive resin 2 of FIGS. 3A and 3B spin coated thereon;

FIG. 6 schematically shows a cross-section of semiconductor substrate 1 after the developing with unhardened photosensitive resin 2 having being eliminated so as to leave hardened photosensitive resin 2;

FIG. 7 shows an outline of a manufacturing line 20 in an embodiment 2 of the present invention;

FIG. 8A schematically shows a cross-section of semiconductor substrate 1 prior to undergoing a heating process 21, with the depressions having been inadequately filled with photosensitive resin 2 due to mask misalignment or underexposure etc.;

FIG. 8B schematically shows a cross-section of semiconductor substrate 1 with the shape of photosensitive resin 2 having been stabilized in heating process 21;

FIG. 9 shows an outline of a manufacturing line 30 in an embodiment 3 of the present invention;

FIG. 10A schematically shows a cross-section of semiconductor substrate 1 prior to undergoing a secondary application process 31, with the depressions having been inadequately filled with photosensitive resin 2 due to mask misalignment or underexposure etc.;

FIG. 10B schematically shows a cross-section of semiconductor substrate 1 with a flattening material 5 having been applied uniformly in secondary application process 31;

FIG. 11 shows an outline of a manufacturing line 40 in an embodiment 4 of the present invention;

FIG. 12 schematically shows a cross-section of a semiconductor substrate 6 (i.e. workpiece) in which cavities have been formed for wiring a silicon IC;

FIG. 13 schematically shows a cross-section of a metal film 7 of substantially uniform thickness having been formed on semiconductor substrate 6 of FIG. 12;

FIG. 14 schematically shows a cross-section of transparent photosensitive resin 2 having been spin coated on semiconductor substrate 6 having metal film 7 of FIG. 13 formed thereon;

FIG. 15 schematically shows a cross-section of a grayscale mask 8 for use with semiconductor substrate 6 being used to expose semiconductor substrate 6 having photosensitive resin 2 of FIG. 14 spin coated thereon;

FIG. 16 schematically shows a cross-section of semiconductor substrate 6 after the developing with unhardened photosensitive resin 2 having being eliminated so as to leave hardened photosensitive resin 2;

FIG. 17 schematically shows a cross-section of semiconductor substrate 6 with etching having been performed until a predetermined material is formed only in the cavities;

FIG. 18A schematically shows a grayscale mask 9 created so that a hardening rate of the photosensitive resin changes according to the shape of surface unevenness and the difference or ratio of etching rates;

FIG. 18B schematically shows a cross-section of FIG. 18A cut at A-A′;

FIG. 19 schematically shows a cross-section of semiconductor substrate 6 having photosensitive resin 2 of FIG. 14 spin coated thereon after being exposed using grayscale mask 9 of FIGS. 18A and 18B and developed, with unhardened photosensitive resin 2 having being eliminated so as to leave hardened photosensitive resin 2; and

FIGS. 20A-20D schematically show cross-sections of exemplary workpieces.

### DETAILED DESCRIPTION OF THE PREFERRED EMBODIMENTS

### Embodiment 1

Outline

An embodiment 1 of the present invention is a manufacturing method for flattening surface unevenness of a workpiece by applying a photosensitive resin to the workpiece surface and exposing the applied photosensitive resin using a grayscale mask that corresponds to the surface shape of the photosensitive resin.

Structure

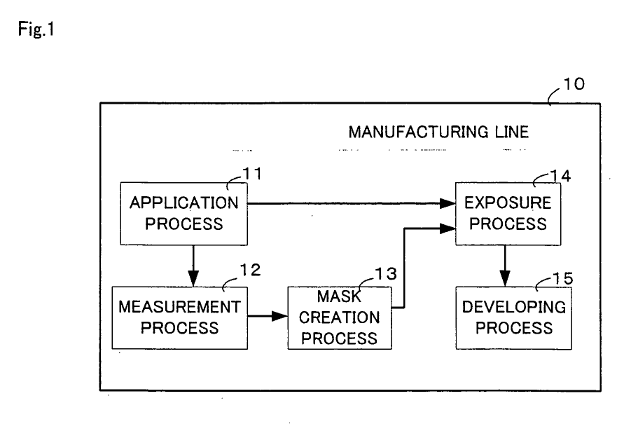

FIG. 1 shows the outline of a manufacturing line 10 in embodiment 1.

As shown in FIG. 1, manufacturing line 10, which is part of a series of lines for manufacturing a semiconductor substrate, for example, includes an application process 11, a measurement process 12, a mask creation process 13, an exposure process 14, and a developing process 15.

Application process 11 involves applying a photosensitive resin uniformly to the uneven surface of a workpiece. In the case of there being depressions (and/or protrusions) of a few microns in depth (height) on the surface of a semiconductor substrate having a solid-state imaging device formed therein, for example, a transparent photosensitive resin is applied on the substrate surface.

Here, a high molecular material whose main component is an acrylic resin, a polyimide resin or an isocyanate resin etc. can be used as the photosensitive resin, with a positive photosensitive resin that softens in places where light is applied being used here.

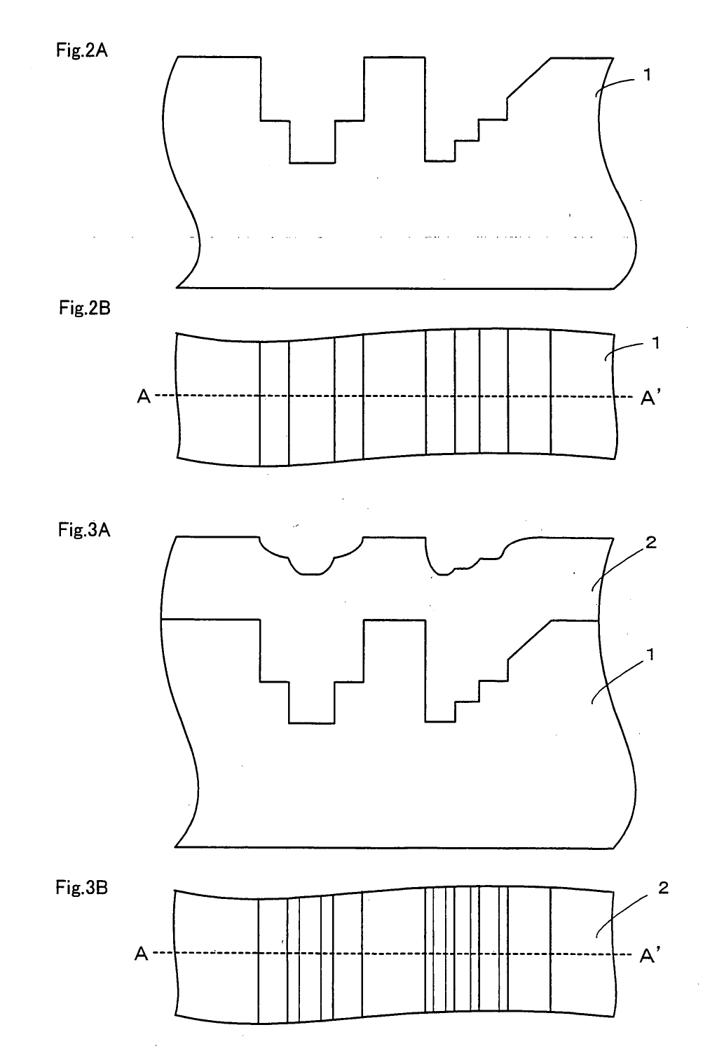

FIG. 2A schematically shows a cross-section of a semiconductor substrate 1 (i.e. workpiece) having a solid-state imaging device formed therein.

FIG. 2B shows FIG. 2A from above, FIG. 2A being the cross-section cut at A-A′.

FIG. 3A schematically shows a cross-section of a transparent photosensitive resin 2 spin coated on semiconductor substrate 1 of FIGS. 2A and 2B.

FIG. 3B shows FIG. 3A from above, FIG. 3A being the cross-section cut at A-A′.

As shown in FIGS. 3A and 3B, the surface of spin-coated photosensitive resin 2 corresponds in shape to the original surface unevenness of the solid-state imaging device.

Measurement process 12 involves measuring the surface shape of photosensitive resin 2 applied in application process 11, using a readily available laser measuring device, contact surface profiler or atomic force microscope (AFM) etc.

Mask creation process 13 involves creating a grayscale mask that corresponds to both the surface shape of photosensitive resin 2 applied in application process 11 and the photosensitivity dependence of film remaining after developing photosensitive resin 2, based on the measurement results from measurement process 12.

Here, the grayscale mask can be generated by applying chromium or the like to a transparent film while varying the transparency per section or by varying the number of fine dots at or below the resolution per section.

The method of creating the grayscale mask is prior art, with description being omitted here given that the method is disclosed in Japanese Patent Application Publication No. 2003-91066 under the title “Concentration Distribution Mask” (Gradation Mask or “GM”).

Here, a test lot is run for each product type before production, with measurement being performed in measurement process 12 and a grayscale mask being created in mask creation process 13.

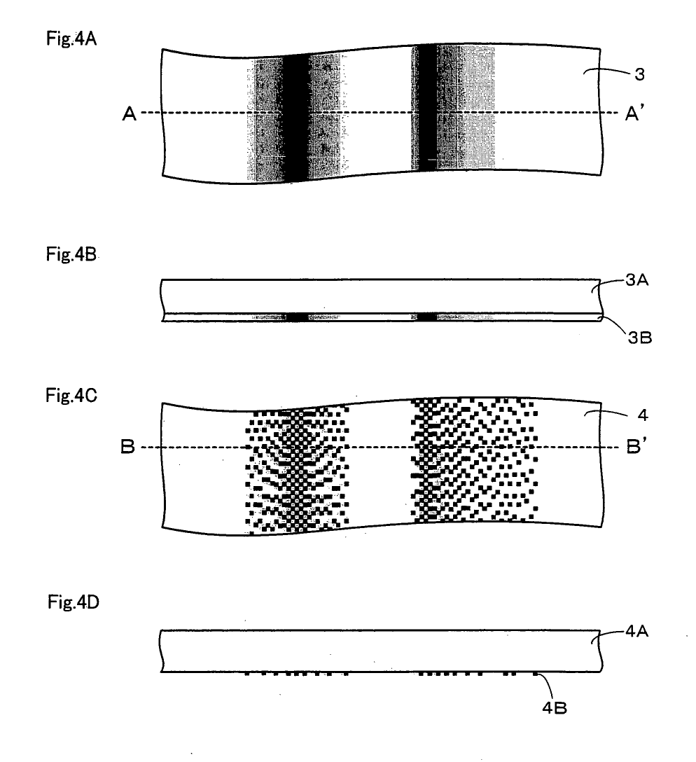

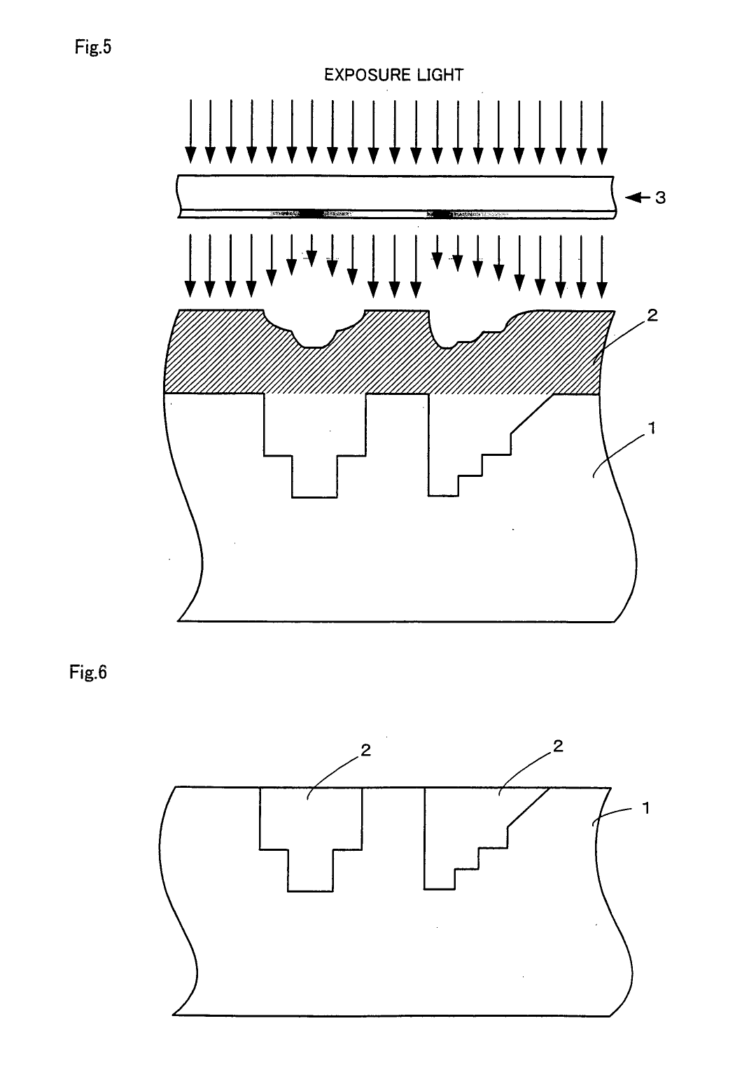

FIG. 4A schematically shows a grayscale mask 3 for use with semiconductor substrate 1 patterned by applying chromium 3B to a transparent film 3A while varying the transparency per section.

FIG. 4B shows a cross-section of FIG. 4A cut at A-A′.

FIG. 4C schematically shows a grayscale mask 4 for use with semiconductor substrate 1 patterned by applying chromium 4B to a transparent film 4A while varying the number of fine dots at or below the resolution per section.

FIG. 4D shows a cross-section of FIG. 4C cut at B-B′.

As shown in FIGS. 4A to 4D, grayscale masks 3 and 4 are created so as to flatten the surface of applied photosensitive resin 2 by reducing the mask transparency in places where depressions exist in the resin surface according to the extent of the depressions, so that when exposed the resin surface is softened according to the extent of the depressions and photosensitive resin 2 remains at the same height throughout. Here, originally flat portions of the resin surface are softened and the concave portions are made to correspond in height to originally flat portions of the substrate surface.

Exposure process 14 involves exposing photosensitive resin 2 using a grayscale mask created in mask creation process 13 to enable the surface of a workpiece to be flattened.

FIG. 5 schematically shows a cross-section of grayscale mask 3 of FIGS. 4A and 4B being used to expose semiconductor substrate 1 having photosensitive resin 2 of FIGS. 3A and 3B spin coated thereon.

Here, the shaded portion of photosensitive resin 2 shown in FIG. 5 is softened as a result of the exposure, with the residual portion remaining in a hardened state.

Developing process 15 involves developing photosensitive resin 2 exposed in exposure process 14 and eliminating photosensitive resin 2 that is not hardened.

FIG. 6 schematically shows a cross-section of semiconductor substrate 1 after the developing with unhardened photosensitive resin 2 having being eliminated so as to leave hardened photosensitive resin 2.

As shown in FIG. 6, unhardened photosensitive resin 2 is eliminated from originally flat portions of the surface of semiconductor substrate 1, so that hardened photosensitive resin 2 remains only in portions of the substrate surface that were originally depressed. The entire substrate surface is thus flattened.

In Summary

As described above, a workpiece can be flattened according to embodiment 1 of the present invention by exposing an applied photosensitive resin using a grayscale mask that corresponds to the surface shape of the photosensitive resin.

Flattening can thus be readily performed in a single operation with a higher degree of flatness than the prior art even in the case of depression of varying depths, thereby facilitating the processing of the surface in a subsequent process.

### Embodiment 2

Outline

An embodiment 2 of the present invention is a manufacturing method for raising the degree of flatness after the completion of all the processes in embodiment 1, by heating the hardened photosensitive resin to stabilize the shape thereof.

Structure

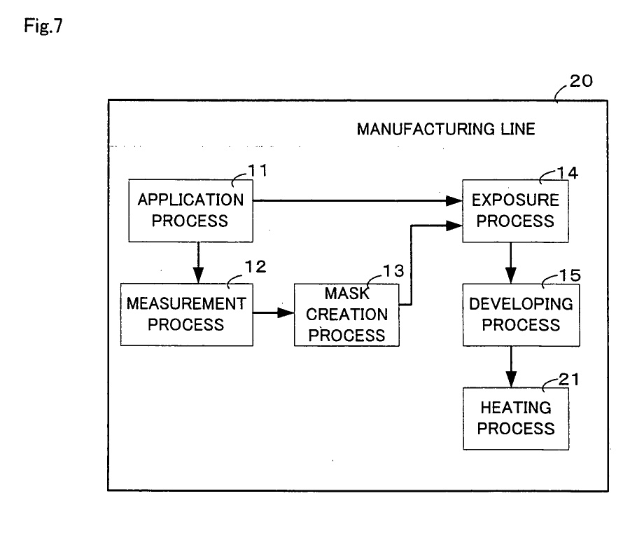

FIG. 7 shows the outline of a manufacturing line 20 in embodiment 2.

As shown in FIG. 7, manufacturing line 20, which is part of a series of lines for manufacturing a semiconductor substrate, the same as manufacturing line 10 in embodiment 1 for example, includes application process 11, measurement process 12, mask creation process 13, exposure process 14, developing process 15, and a heating process 21, the only difference with manufacturing line 10 being the addition of heating process 21.

The same reference signs are assigned to elements that are the same as embodiment 1, with description of these elements being omitted here.

Heating process 21 involves raising the degree of flatness by heating the workpiece on which hardened photosensitive resin 2 remains as a result of developing process 15 at a temperature that exceeds the glass softening point, so as to soften the hardened photosensitive resin and thus stabilize the shape of the resin.

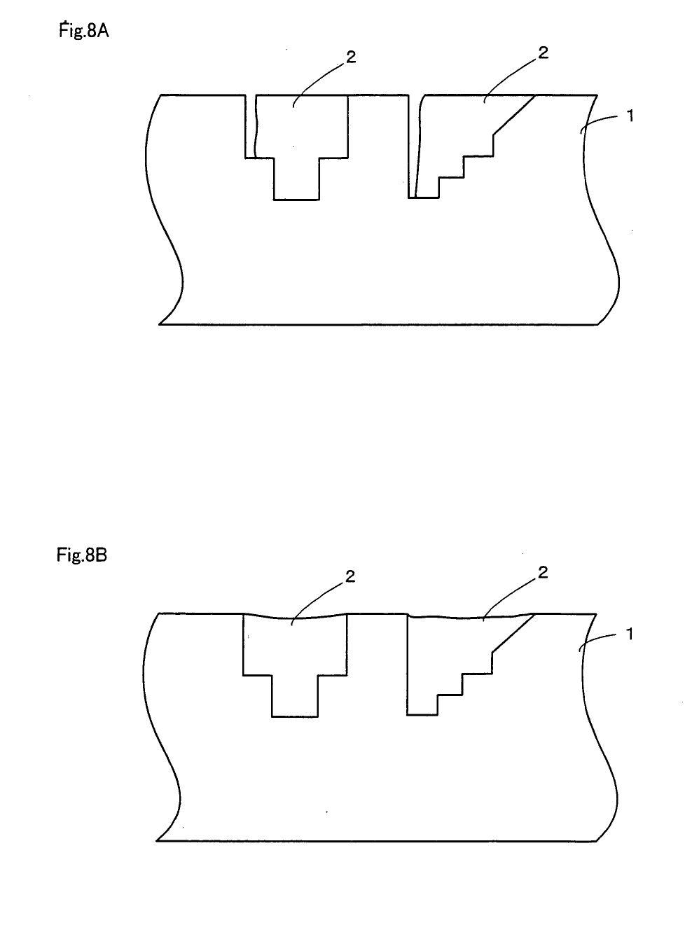

FIG. 8A schematically shows a cross-section of semiconductor substrate 1 prior to undergoing heating process 21, with the depressions having been inadequately filled with photosensitive resin 2 due to mask misalignment or underexposure etc.

FIG. 8B schematically shows a cross-section of semiconductor substrate 1 with the shape of photosensitive resin 2 having been stabilized in heating process 21.

As shown in FIG. 8B, the degree of flatness is raised as a result of the shape of photosensitive resin 2 being stabilized in heating process 21.

In Summary

As described above, hardened photosensitive resin is softened to stabilized the shape thereof by applying heat after the developing according to embodiment 2, allowing depressions inadequately filled with photosensitive resin due to mask misalignment or underexposure etc. to be filled in and flattened.

### Embodiment 3

Outline

An embodiment 3 of the present invention is a manufacturing method for raising the degree of flatness after the completion of all the processes in embodiment 1, by uniformly applying a flattening material.

Structure

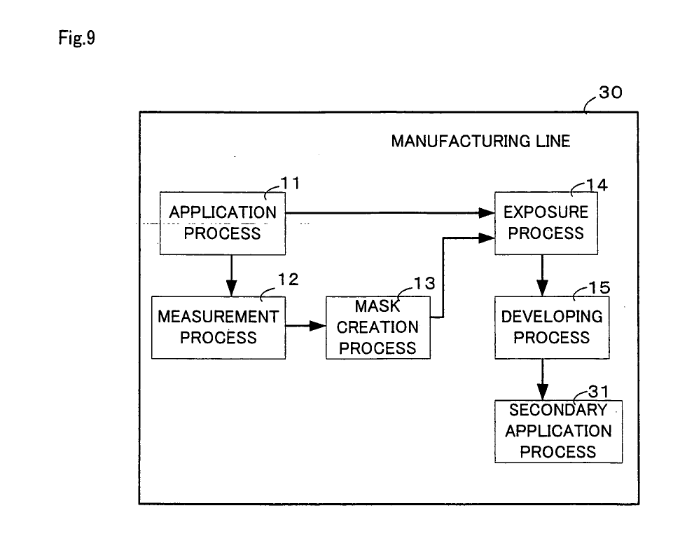

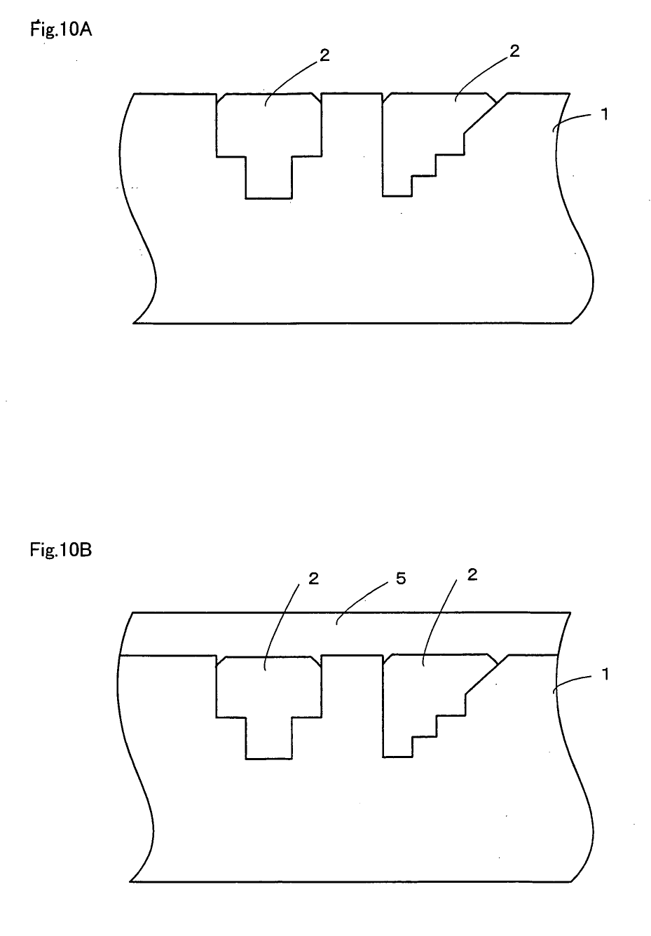

FIG. 9 shows the outline of a manufacturing line 30 in embodiment 3.

As shown in FIG. 9, manufacturing line 30, which is part of a series of lines for manufacturing a semiconductor substrate, the same as manufacturing line 10 in embodiment 1 for example, includes application process 11, measurement process 12, mask creation process 13, exposure process 14, developing process 15, and a secondary application process 31, the only difference with manufacturing line 10 being the addition of secondary application process 31.

The same reference signs are assigned to elements that are the same as embodiment 1, with description of these elements being omitted here.

Secondary application process 31 involves raising the degree of flatness by applying a flattening material (e.g. non-photosensitive resin) uniformly to the surface of the workpiece on which hardened photosensitive resin 2 remains as a result of developing process 15.

FIG. 10A schematically shows a cross-section of semiconductor substrate 1 prior to undergoing secondary application process 31, with the depressions having been inadequately filled with photosensitive resin 2 due to mask misalignment or underexposure etc.

FIG. 10B schematically shows a cross-section of semiconductor substrate 1 with a flattening material 5 having been applied uniformly in secondary application process 31.

As shown in FIG. 10B, the degree of flatness is raised by the uniform application of flattening material 5 in secondary application process 31.

In Summary

As described above, a flattening material is applied uniformly after the developing according to embodiment 3, allowing depressions inadequately filled with photosensitive resin due to mask misalignment or underexposure etc. to be filled in and flattened. This is particularly effective in relation to depressions of 1 μm or less in a plane direction.

### Embodiment 4

Outline

An embodiment 4 of the present invention is a manufacturing method for flattening the surface of a workpiece by forming a cavity in the surface, forming a film of uniform thickness made from a metal or an insulator etc., applying a photosensitive resin, exposing the applied resin using a grayscale mask that corresponds to the surface shape of photosensitive resin, and performing directional dry etching.

Structure

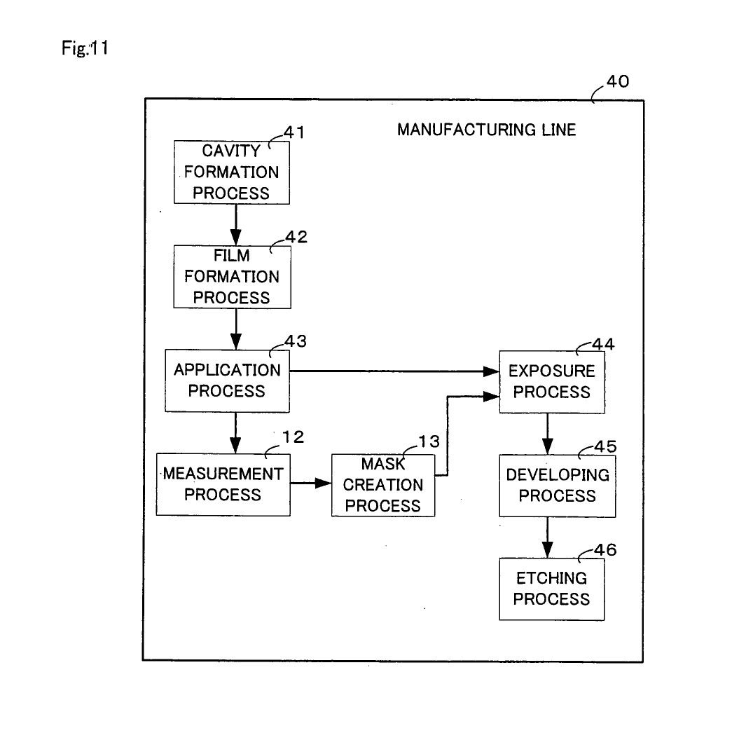

FIG. 11 shows the outline of a manufacturing line 40 in embodiment 4.

As shown in FIG. 11, manufacturing line 40, which is part of a series of lines for manufacturing a semiconductor substrate, the same as manufacturing line 10 in embodiment 1 for example, includes a cavity formation process 41, a film formation process 42, an application process 43, measurement process 12, mask creation process 13, an exposure process 44, a developing process 45, and an etching process 46.

The same reference signs are assigned to elements that are the same as embodiment 1, with description of these elements being omitted here.

Cavity formation process 41 involves forming a cavity by using directional dry etching to hollow out part of the workpiece where a wiring pattern or insulating film is to be formed. In the given example this involves forming cavities in an insulating film for wiring a silicon IC.

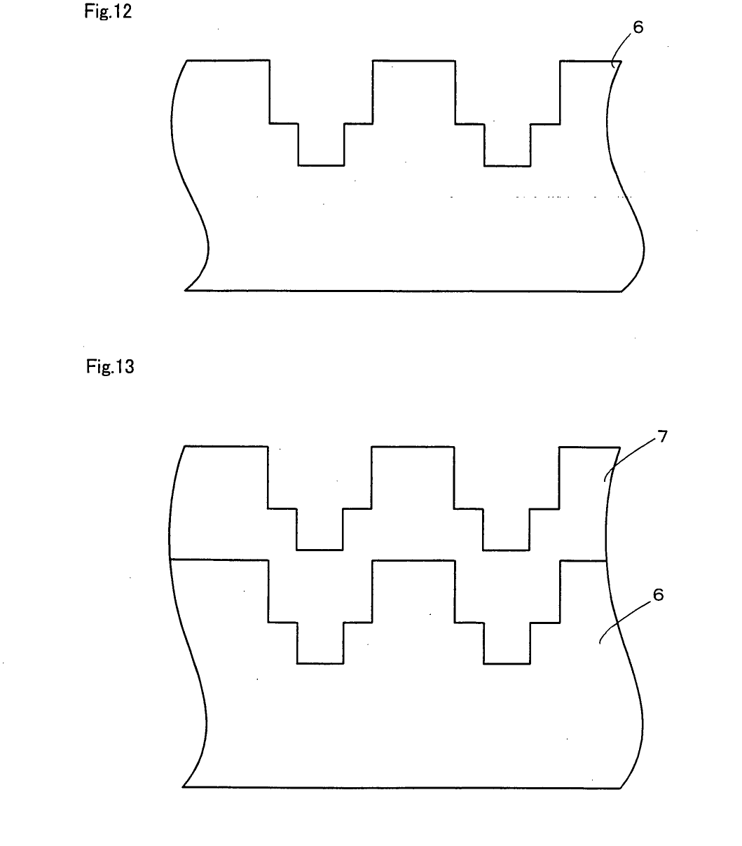

FIG. 12 schematically shows a cross-section of a semiconductor substrate 6 (i.e. workpiece) in which cavities have been formed for wiring a silicon IC.

Film formation process 42 involves using any of a variety of thin film growth techniques etc. to form a film of substantially uniform thickness on the workpiece in which cavities have been formed as a result of cavity formation process 41, with a predetermined material such as a metal (e.g. copper, aluminum) or an insulator (e.g. silicon dioxide SiO₂, silicon nitride Si₃O₄).

FIG. 13 schematically shows a cross-section of a metal film 7 of substantially uniform thickness having been formed on semiconductor substrate 6 of FIG. 12.

As shown in FIG. 13, the surface of metal film 7 formed at a substantially uniform thickness approximately matches the original surface unevenness of the silicon IC.

Application process 43 involves applying a photosensitive resin uniformly to the surface of the workpiece on which the film of substantially uniform thickness has been formed as a result of film formation process 42. In the given example this involves spin coating transparent photosensitive resin 2 on the surface of semiconductor substrate 6 in which cavities have been formed for wiring the silicon IC, with metal film 7 of substantially uniform thickness having been formed thereon.

Here, the photosensitive resin is the same as embodiment 1.

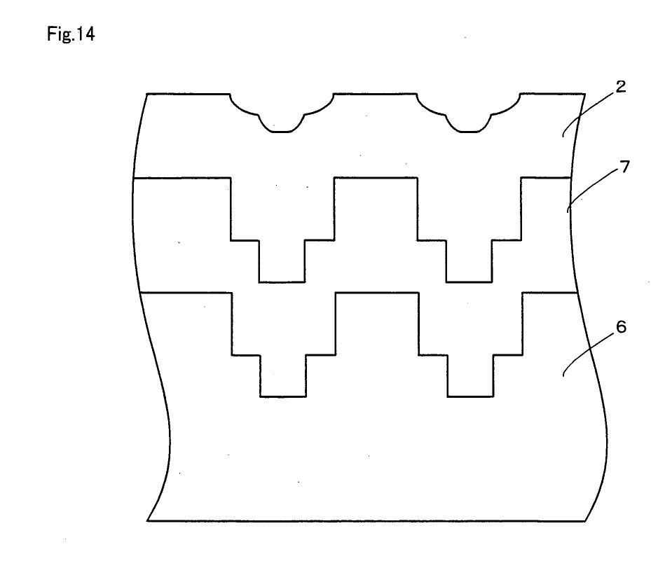

FIG. 14 schematically shows a cross-section of transparent photosensitive resin 2 having been spin coated on semiconductor substrate 6 having metal film 7 of FIG. 13 formed thereon.

As shown in FIG. 14, the surface of spin-coated photosensitive resin 2 corresponds in shape to the cavities formed in the surface of the silicon IC.

Exposure process 44 involves exposing photosensitive resin 2 using a grayscale mask created in mask creation process 13 to enable the surface of the workpiece to be flattened.

FIG. 15 schematically shows a cross-section of a grayscale mask 8 for use with semiconductor substrate 6 being used to expose semiconductor substrate 6 having photosensitive resin 2 of FIG. 14 spin coated thereon.

Here, the shaded portion of photosensitive resin 2 in FIG. 15 is softened by exposure, while the residual resin remains in a hardened state.

Developing process 45 involves developing photosensitive resin 2 exposed in exposure process 44 and eliminating unhardened photosensitive resin.

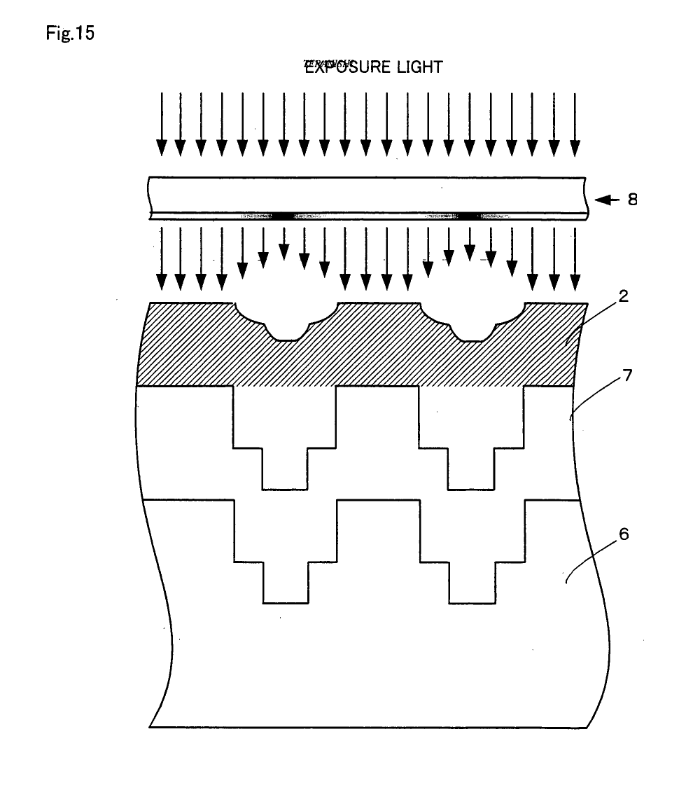

FIG. 16 schematically shows a cross-section of semiconductor substrate 6 after the developing with unhardened photosensitive resin 2 having being eliminated so as to leave hardened photosensitive resin 2.

As shown in FIG. 16, the entire surface has been flattened, with unhardened photosensitive resin 2 having been eliminated from portions of the metal film where cavities are not formed in the surface of semiconductor substrate 6, so that hardened photosensitive resin 2 remains only on portions of the metal film where cavities are formed.

Etching process 46 involves uniformly performing directional dry etching on the surface of the workpiece on which hardened photosensitive resin remains in cavities in the film formed as result of film formation process 42, to thus flatten the surface of the workpiece. Here, etching is performed until the predetermined material is formed only in the cavities.

FIG. 17 schematically shows a cross-section of semiconductor substrate 6 with etching having been performed until the predetermined material is formed only in the cavities.

As shown in FIG. 17, metal film 7 is etched from portions of the surface of semiconductor substrate 6 on which cavities are not formed, so that metal film 7 remains only in portions where the cavities are formed and the entire surface is flattened.

Note that the exposure of photosensitive resin in exposure process 44 to enable the surface of the workpiece to be flattened assumes that the etching rates of the predetermined material and the hardened photosensitive resin are substantially the same. If these etching rates differ the rate at which the photosensitive resin is hardened needs to be changed according to the shape of the surface unevenness and the difference or ratio of the etching rates.

Here, methods for changing the hardening rate of photosensitive resin include manipulating the exposure time, or creating the grayscale mask so that the hardening rate of the photosensitive resin changes according to the shape of the surface unevenness and the difference or ratio of the etching rates.

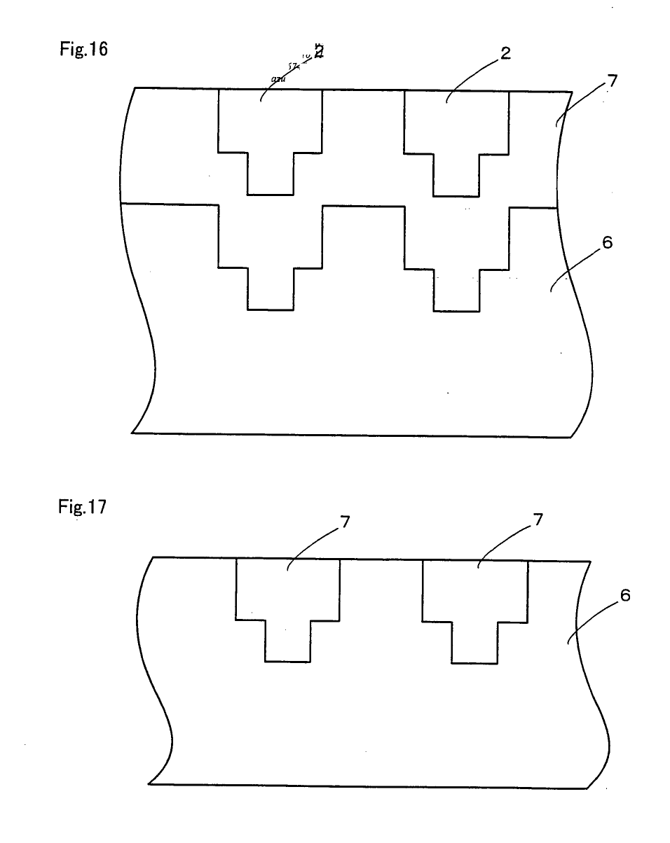

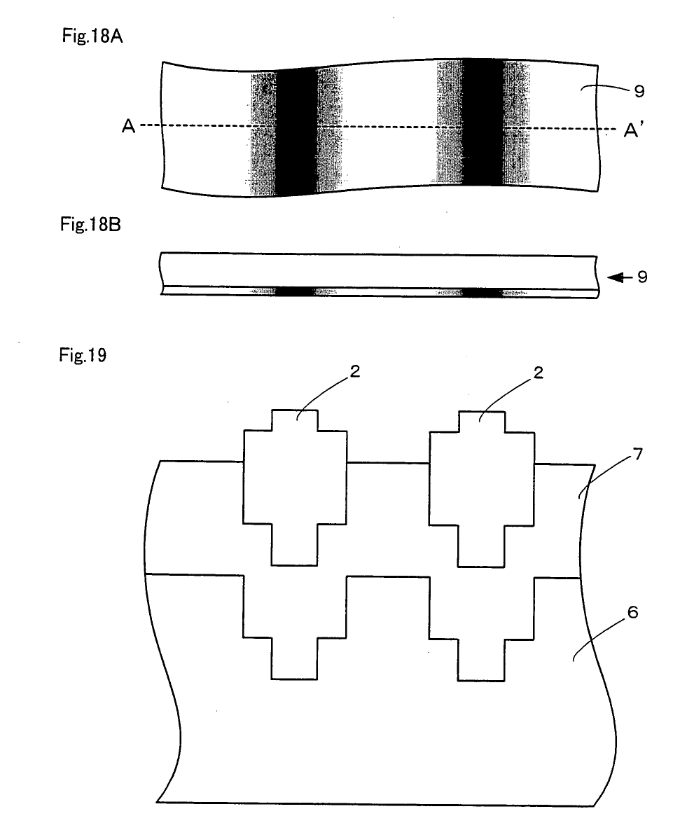

FIG. 18A schematically shows a grayscale mask 9 created so that the hardening rate of the photosensitive resin changes according to the shape of the surface unevenness and the difference or ratio of etching rates.

FIG. 18B schematically shows a cross-section of FIG. 18A cut at A-A′.

FIG. 19 schematically shows a cross-section of semiconductor substrate 6 having photosensitive resin 2 of FIG. 14 spin coated thereon after being exposed using grayscale mask 9 of FIGS. 18A and 18B and developed, with unhardened photosensitive resin 2 having being eliminated so as to leave hardened photosensitive resin 2.

As shown in FIG. 19, unhardened photosensitive resin 2 has been eliminated from portions of the metal film where cavities are not formed in semiconductor substrate 6, while hardened photosensitive resin 2 remaining only on portions of the metal film where cavities are formed, according to the shape of the surface unevenness and the difference or ratio of etching rates.

In Summary

As described above, an applied photosensitive resin is exposed using a grayscale mask that corresponds to the surface shape of the photosensitive resin according to embodiment 4, enabling a semiconductor substrate to be flattened using a metal or insulator etc.

Flattening can thus be readily performed in a single operation with a higher degree of flatness than the prior art even when cavities vary in depth, thus facilitating the processing of the workpiece surface in a subsequent process.

In particular, a high degree of flatness is required in the case of a solid-state imaging device since the degree of flatness achieved in the flattening operation prior to forming a color filter or a micro lens contributes directly to device performance. Because flattening can be performed in a single operation according to the present invention, the flattening operation can be realized with a high degree of flatness and with simple processes, without the risk when flattening is performed over a plurality of process of the processes becoming out of sync with one another.

Note that the surface unevenness of the workpiece used in the above description was merely by way of example. The present invention is applicable whatever form the unevenness takes.

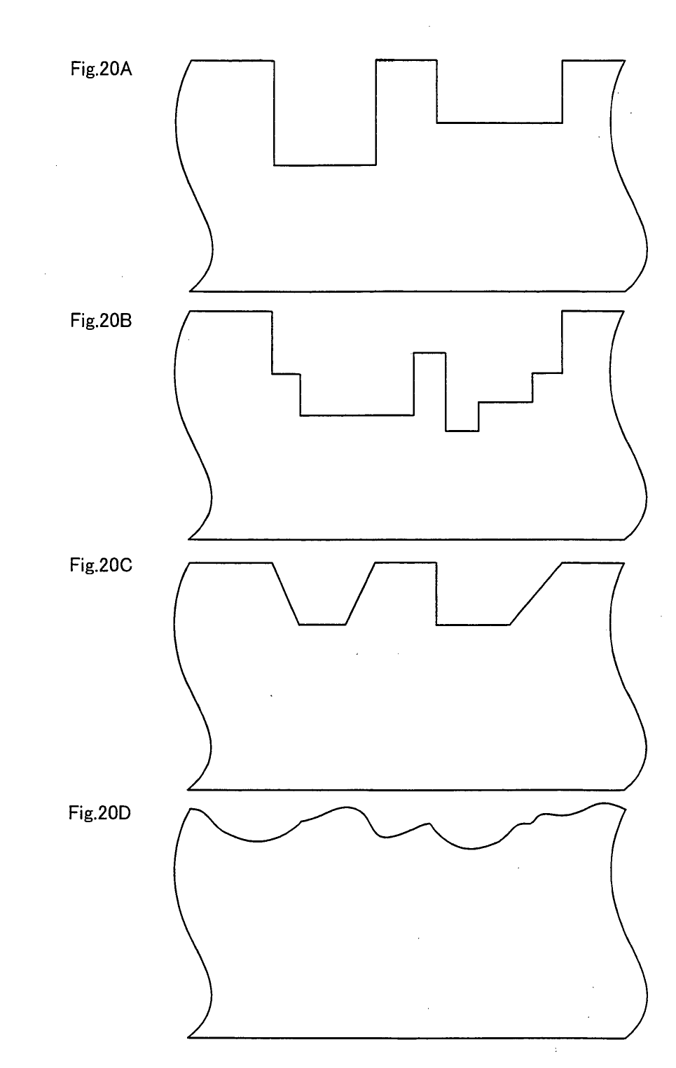

FIGS. 20A to 20D schematically show cross-sections of exemplary workpieces.

All manner of unevenness was assumed in arriving at the preferred embodiments of the present invention, and these embodiments can be realized with respect to all cases including the following: depressions differing in depth as shown in FIG. 20A; depressions having three or more changes in height over a wide area as shown in FIG. 20B; depressions differing in slope as shown in FIG. 20C; and unevenness that is particularly irregular as shown in FIG. 20D.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

### INDUSTRIAL APPLICABILITY

The present invention can be widely applied to precision processed products on which microprocessing is performed such as semiconductor devices and micromachines.

The present invention enables surface unevenness to be flattened before a subsequent process with a higher degree of flatness than the prior art, making more detailed processing possible. The industrial applicability of the present invention is thus extremely high.

What is claimed is:

1. A manufacturing method for flattening surface unevenness of a workpiece to facilitate processing of the workpiece surface in a subsequent step, comprising:
an application step of applying a photosensitive resin over the workpiece surface;
an exposure step of exposing the applied photosensitive resin using a grayscale mask that corresponds to a surface shape of the photosensitive resin; and
a developing step of developing the exposed photosensitive resin and eliminating unhardened photosensitive resin.

2. The manufacturing method of claim 1, wherein
the photosensitive resin is exposed in the exposure step to enable the workpiece surface to be flattened, and
the manufacturing method further comprises, after the developing step, a heating step of increasing a degree of flatness by applying heat and softening hardened photosensitive resin.

3. The manufacturing method of claim 1, wherein
the photosensitive resin is exposed in the exposure step to enable the workpiece surface to be flattened, and
the manufacturing method further comprises, after the developing step, a secondary application step of increasing a degree of flatness by applying a flattening material uniformly on the workpiece surface.

4. The manufacturing method of claim 1 further comprising, before the application step, a film formation step of forming a film of substantially uniform thickness on the workpiece surface using a predetermined material, wherein
the photosensitive resin is applied on the film in the application step, and
the manufacturing method further comprises, after the developing step, an etching step of flattening the workpiece surface by uniformly etching the workpiece surface on which hardened photosensitive resin remains in depressions in the film.

5. The manufacturing method of claim 4 further comprising, before the film formation step, a cavity formation step of forming a cavity by hollowing out part of the workpiece surface where the predetermined material is to be formed, wherein
the etching is performed in the etching step until the predetermined material is formed only in the cavity.

6. The manufacturing method of claim 4, wherein
the predetermined material and the hardened photosensitive resin have substantially the same etching rate, and
the photosensitive resin is exposed in the exposure step to enable the workpiece surface to be flattened.

7. The manufacturing method of claim 4, wherein
the predetermined material and the hardened photosensitive resin have different etching rates, and
in the exposure step, a hardening rate of the photosensitive resin is changed according to a shape of the surface unevenness and a difference or a ratio of the etching rates.

8. The manufacturing method of claim 4, wherein
the predetermined material and the hardened photosensitive resin have different etching rates, and
the grayscale mask is created so that a hardening rate of the photosensitive resin changes according to a shape of the surface unevenness and a difference or a ratio of the etching rates.

9. The manufacturing method of claim 4, wherein
the workpiece is a semiconductor substrate, and
the predetermined material is any of copper, aluminum, silicon dioxide, and silicon nitride.

10. The manufacturing method of claim 1, wherein the workpiece is one of a semiconductor substrate and a micromachine.
